(19) United States
(12) Patent Application Publication
(10) Pub. No.: US 2024/0378862 A1
(43) Pub. Date: Nov. 14, 2024

(54) APPARATUS, SYSTEM, AND METHOD OF DETERMINING FUSE STATE BASED ON DEEP LEARINING

(71) Applicant: REPUBLIC OF KOREA (NATIONAL FORENSIC SERVICE DIRECTOR MINISTRY OF THE INTERIOR AND SAFETY), Wonju-si (KR)

(72) Inventors: Kyu Young LIM, Wonju-si (KR); Young Il SEO, Wonju-si (KR); Byung Seon MOON, Busan (KR); Jin Pyo KIM, Daejeon (KR)

(21) Appl. No.: 18/227,043

(22) Filed: Jul. 27, 2023

(30) Foreign Application Priority Data
May 10, 2023 (KR) 10-2023-0060530

(51) Int. Cl. G06V 10/774; G01N 23/04; G01N 23/083; G01N 23/18; G06T 7/11; G06V 10/764; G06V 10/77; G06V 10/82

(52) U.S. Cl. CPC G06V 10/774; G01N 23/043; G01N 23/083; G01N 23/18; G06T 7/11; G06V 10/764; G06V 10/7715; G06V 10/82; G06T 2207/10064; G06T 2207/20076

(57) ABSTRACT

A deep learning-based fuse state determination apparatus includes an image obtaining unit configured to obtain a fluoroscopic image of an object including a fuse, a fuse area extraction unit configured to extract a fuse area from the fluoroscopic image of the object, a trained model application unit configured to calculate a probability (determination probability) of determining a fuse state of the extracted fuse area as a fuse state of set classification by applying a pre-trained model, and a fuse state determination unit configured to determine the fuse state of the extracted fuse area according to a set determination condition.

### CROSS-REFERENCE TO RELATED APPLICATIONS

The present application is based on and claims priority to Korean Patent Application No. 10-2023-0060530 filed on May 10, 2023, in the Korean Intellectual Property Office, which is incorporated herein by reference in its entirety.

### BACKGROUND

### 1. Field

One or more embodiments relate to an apparatus, system, and method of determining a fuse state based on deep learning.

### 2. Description of the Related Art

A fuse is an electrical safety device designed to protect electrical circuits and devices from damage caused by excessive current (overload, short circuit, etc.). The fuse includes a wire or filament (a fuse element) made of a material with a low melting point such as tin, lead, or aluminum. When a current flowing in a circuit exceeds a rated value of the fuse, a wire of the fuse is heated and melted to cut off the circuit, thereby preventing further damage to a device or wiring.

When the possibility of a fire caused by electrical causes is suspected in an electronic product, a fuse state of the product may be an important evidence to prove whether or not the fire is caused by electrical causes.

When a fuse is melted or scattered, there is a possibility that an overcurrent has flowed through the fuse or an electrical singularity has been formed on a load side connected to the fuse. However, when a fire occurs and a fuse is melted by a flame, traces of melting or scattering of a fuse element may become vague or disappear.

As a method of confirming a state of a fuse of an electric circuit board, a method of confirming fine melting traces using a microscope or confirming fuse melting traces through X-ray imaging is used.

Among these, when imaging a fuse using X-ray, interference such as soot that may be attached to a fuse surface can be minimized and a metal component is clearly shown, so X-ray imaging is the most suitable method for confirming a fuse state.

However, even with X-ray imaging, when a fuse is severely melted by a flame, it is difficult to determine whether the fuse is melted or scattered by an electrical cause (overcurrent, etc.) or melted by a flame.

### SUMMARY

One or more embodiments include an apparatus and method capable of improving the accuracy of determining a fuse state by applying an algorithm for extracting and analyzing a fuse area using semantic segmentation from among deep learning techniques.

One or more embodiments include an apparatus and method capable of determining a fuse state appearing in an image by classifying the fuse state into thermal fuse disconnection, thermal fuse non-disconnection, tubular fuse non-melting, tubular fuse melting or scattering, or tubular fuse flame melting by utilizing a convolutional neural network (CNN) from among deep learning techniques.

According to one or more embodiments, a deep learning-based fuse state determination apparatus includes an image obtaining unit configured to obtain a fluoroscopic image of an object including a fuse, a fuse area extraction unit configured to extract a fuse area from the fluoroscopic image of the object, a trained model application unit configured to calculate a probability (determination probability) of determining a fuse state of the extracted fuse area as a fuse state of set classification by applying a pre-trained model, and a fuse state determination unit configured to determine the fuse state of the extracted fuse area according to a set determination condition.

In an embodiment, the fuse area extraction unit may extract the fuse area from the fluoroscopic image of the object by using semantic segmentation.

In an embodiment, the fuse state of the set classification may include thermal fuse disconnection, thermal fuse non-disconnection, tubular fuse non-melting, tubular fuse melting or scattering, or tubular fuse flame melting.

In an embodiment, the set determination condition may include determining a fuse state having the highest determination probability and greater than or equal to a reference value from among fuse states of set classification.

In an embodiment, the deep learning-based fuse state determination apparatus may further include a trained model generation unit configured to generate the pre-trained model by using fluoroscopic images of an object including a fuse used in an appraisal report as training data.

In an embodiment, the pre-trained model may be a convolutional neural network (CNN)-based deep learning model.

According to one or more embodiments, a deep learning-based fuse state determination system includes a deep learning-based fuse state determination apparatus configured to extract a fuse area from a fluoroscopic image of an object including a fuse and determine a fuse state of the extracted fuse area by applying a pre-trained model, and a server receiving user input text information related to the fuse state and configured to provide an fluoroscopic image of an object including a fuse based on the user input text information.

According to one or more embodiments, a deep learning-based fuse state determination method includes obtaining a fluoroscopic image of an object including a fuse, extracting a fuse area from the fluoroscopic image of the object, calculating a probability (determination probability) of determining a fuse state of the extracted fuse area as a fuse state of set classification by applying a pre-trained model, and determining the fuse state of the extracted fuse area according to a set determination condition.

In an embodiment, the fuse state of the set classification may include thermal fuse disconnection, thermal fuse non-disconnection, tubular fuse non-melting, tubular fuse melting or scattering, or tubular fuse flame melting.

In an embodiment, the deep learning-based fuse state determination method may further include generating the pre-trained model by using fluoroscopic images of an object including a fuse used in an appraisal report as training data.

In an embodiment, the generating of the pre-trained model may include obtaining fluoroscopic images of an object including a fuse used in an appraisal report, extracting a fuse area from a fluoroscopic image of the object, and generating a CNN-based deep learning model by using an image of the extracted fuse area as training data.

In an embodiment, the obtaining of the fluoroscopic images of the object including the fuse used in the appraisal report may include obtaining user input text information related to a fuse state, and receiving, by a server, the user input text information and providing a fluoroscopic image of an object including a fuse based on the user input text information.

Additional aspects will be set forth in part in the description which follows and, in part, will be apparent from the description, or may be learned by practice of the embodiments.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic block diagram of a system and apparatus for determining a fuse state based on deep learning according to an embodiment;

FIGS. 2A to 2E are views illustrating fuse states included in fluoroscopic images by way of example;

FIG. 3 is a flowchart illustrating a deep learning-based fuse state determination method according to an embodiment;

FIG. 4 is a view for explaining extracting a fuse area from a fluoroscopic image of an object including a fuse;

FIG. 5 is a flowchart illustrating generating a pre-trained model according to an embodiment; and

FIG. 6 is a view illustrating an operation according to a deep learning-based fuse state determination system according to an embodiment.

### DETAILED DESCRIPTION

Hereinafter, embodiments will be described in detail with reference to the accompanying drawings. The same reference numerals are used to denote the same elements, and repeated descriptions thereof will be omitted. It will be understood that although the terms “first,” “second,” etc. may be used herein to describe various elements, these elements should not be limited by these terms.

An expression used in the singular encompasses the expression of the plural, unless it has a clearly different meaning in the context. It will be further understood that the terms “comprises” and/or “comprising” used herein specify the presence of stated features or components, but do not preclude the presence or addition of one or more other features or components.

Sizes of elements in the drawings may be exaggerated for convenience of explanation. In other words, since sizes and thicknesses of components in the drawings are arbitrarily illustrated for convenience of description, the following embodiments are not limited thereto. When a certain embodiment may be implemented differently, a specific process order may be performed differently from the described order. For example, two consecutively described processes may be performed substantially at the same time or performed in an order opposite to the described order.

In this specification, a “fuse” is an electrical safety device designed to protect electrical circuits and devices from damage caused by excessive current (overload, short circuit, etc.). A “thermal fuse” is a safety device that prevents overheating, a small heat-sensitive device designed to open a circuit when a certain temperature is reached. A “tubular fuse” is a safety device that prevents overcurrent and is formed in a cylindrical shape made of ceramic or glass and has metal contacts at each end. Inside the tubular fuse, a thin wire or filament is placed, and when a current exceeds a certain value, the wire or filament is cut off to cut off a circuit.

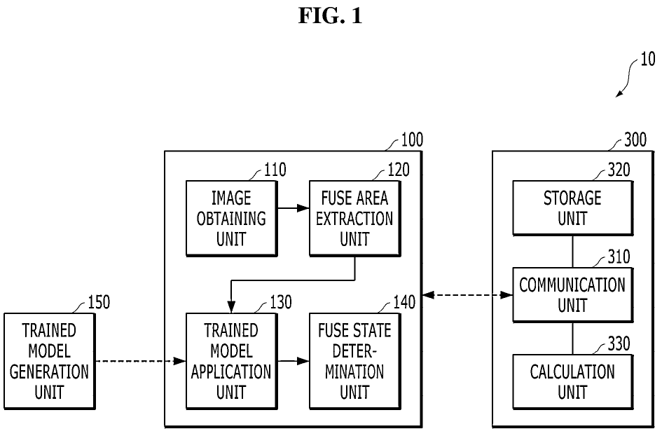

FIG. 1 is a schematic block diagram of a system and apparatus for determining a fuse state based on deep learning according to an embodiment.

Referring to FIG. 1, a deep learning-based fuse state determination system 10 according to an embodiment may include a deep learning-based fuse state determination apparatus 100 and a server 300.

The deep learning-based fuse state determination system 10 according to an embodiment may generate a pre-trained model by collecting a large amount of fluoroscopic images of fuse-containing objects collected and photographed from actual fire sites used in an appraisal report, and then may determine a fuse state from the fluoroscopic images obtained at the fire sites.

The deep learning-based fuse state determination apparatus 100 may be an apparatus that determines and displays a fuse state from a fluoroscopic image obtained at a fire site.

The deep learning-based fuse state determination apparatus 100 may be various types of information processing devices used by users. For example, the deep learning-based fuse state determination apparatus 100 may be a personal computer (PC), a laptop computer, a mobile phone, a tablet PC, a smart phone, or a personal digital assistant (PDA). The deep learning-based fuse state determination apparatus 100 may be borrowed without limitation as long as an application for which the deep learning-based fuse state determination method 200 provided by an embodiment is programmed can be loaded.

The deep learning-based fuse state determination apparatus 100 shown in FIG. 1 shows only components related to the present embodiment in order to prevent features of the present embodiment are blurred.

The deep learning-based fuse state determination apparatus 100 according to an embodiment may include an image obtaining unit 110, a fuse area extraction unit 120, a trained model application unit 130, and a fuse state determination unit 140.

The image obtaining unit 110 may obtain a fluoroscopic image of an object including a fuse.

For example, the fluoroscopic image of the object may include an X-ray image or a CT image.

As an embodiment, the image obtaining unit 110 may obtain an X-ray image of an electric circuit board including a fuse found at a fire site.

The image obtaining unit 110 may obtain a fluoroscopic image by directly photographing an object including a fuse. In addition, the image obtaining unit 110 may receive a fluoroscopic image of an object including a fuse through transmission from another photographing device or the server 300.

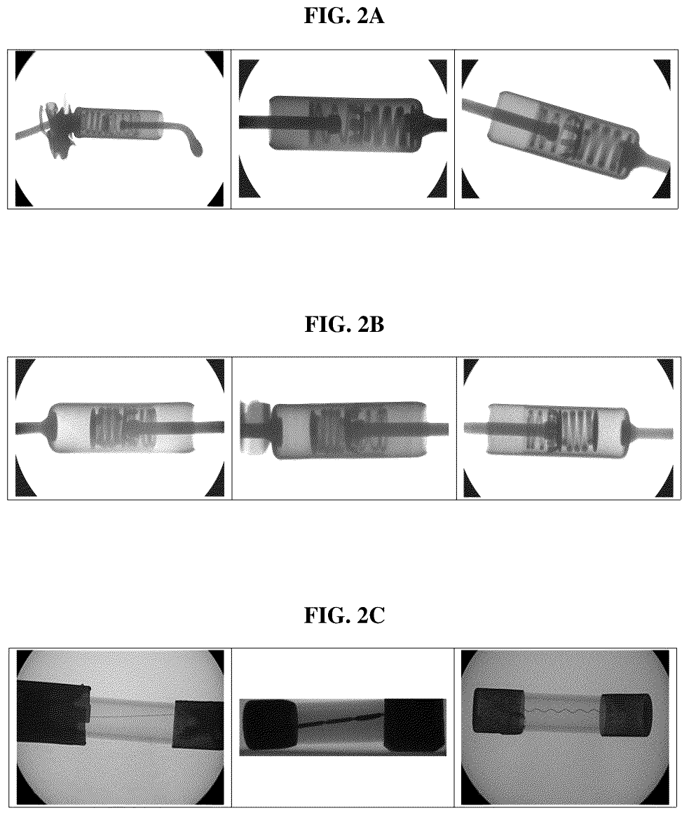

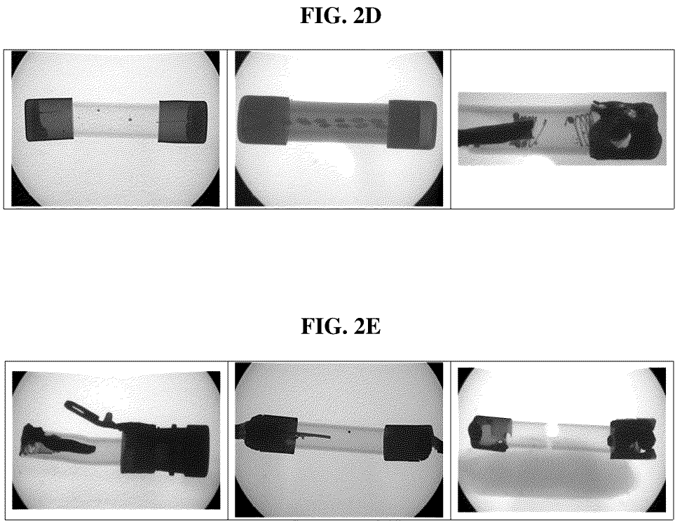

FIGS. 2A to 2E are views illustrating fuse states included in fluoroscopic images by way of example. Referring to FIGS. 2A to 2E, the fuse states are classified into thermal fuse disconnection (FIG. 2A), thermal fuse non-disconnection (FIG. 2B), tubular fuse non-melting (FIG. 2C), tubular fuse melting or scattering (FIG. 2D), or tubular fuse flame melting (FIG. 2E).

The fuse area extraction unit 120 may extract a fuse area from a fluoroscopic image of an object.

As an embodiment, the fuse area extraction unit 120 may extract a fuse area from a fluoroscopic image of an object by using semantic segmentation.

Semantic segmentation typically uses a convolutional neural network (CNN) to extract features from an image and classifies each pixel into a specific class. Semantic segmentation may more accurately segment and extract a specific object from an image.

For example, models of semantic segmentation include fully convolutional network for semantic segmentation (FCN), SegNet, or Unet.

The trained model application unit 130 may calculate a probability (determination probability) of determining a fuse state of an extracted fuse area as a fuse state of set classification by applying a pre-trained model.

The pre-trained model applied here may be a CNN-based deep learning model (CNN model). The CNN model recognizes unique patterns of images and classify the images based on the unique patterns. For example, in more detail, the CNN model may be any one of ALEXNET, ZFNET, VGGNET, GOOGLENET, RESNET, WIDE RESNET, VGG19, INCEPTION V3, INCEPTION V4, XCEPTION, SQUEEZENET, DENSENET, and MOBILENETS.

The trained model application unit 130 may determine a fuse state by classifying it into a total of five fuse states: thermal fuse disconnection, thermal fuse non-disconnection, tubular fuse non-melting, tubular fuse melting or scattering, and tubular fuse flame melting. A determination result of each state is output as a numerical value (%) and may be expressed as a determination probability.

The fuse state determination unit 140 may determine a fuse state of an extracted fuse area according to a set determination condition.

In more detail, the fuse state determination unit 140 may determine a fuse state of an extracted fuse area as a fuse state that satisfies a set determination condition. In addition, the fuse state determination unit 140 may determine the fuse state as ‘indeterminable’ when the fuse state does not satisfy the set determination condition.

The fuse state that satisfies the set determination condition may be a fuse state having the highest determination probability from among fuse states of set classification and having a reference value or higher.

Accordingly, the fuse state determination unit 140 may determine the fuse state as one of thermal fuse disconnection, thermal fuse non-disconnection, tubular fuse non-melting, tubular fuse melting or scattering, and tubular fuse flame melting. The fuse state determination unit 140 may determine the fuse state as ‘indeterminable’ when the fuse state does not satisfy the set determination condition.

For example, when a reference probability is 70.00% or more and a determination probability of tubular fuse melting or scattering is 89.15%, the fuse state determination unit 140 may determine that the fuse state as ‘tubular fuse melting or scattering’. In addition, when a reference probability is 70.00% or more and a determination probability of tubular fuse melting or scattering is 59.15%, the fuse state determination unit 140 may determine the fuse state as ‘indeterminable’.

In addition, the deep learning-based fuse state determination apparatus 100 according to an embodiment may further include a trained model generation unit 150.

The trained model generation unit 150 may generate a pre-trained model by using fluoroscopic images of an object including a fuse used in an appraisal report as training data. The appraisal report refers to a document that describes an appraisal process and its results based on the expert knowledge and experience of an appraiser. The appraisal report may include fuse-related images found at fire, explosion, or arson sites, so the fuse-related images included in the appraisal report may be used to generate a pre-trained model.

Even if a fuse is melted or scattered by an overcurrent or the like, when the fuse is melted again by a flame, melting or scattering traces may be damaged and the classification may be ambiguous. Accordingly, in embodiments, common features are extracted through learning on a large amount of images found at actual fire sites, and a fuse state can be determined based on this.

The trained model generation unit 150 may be included in the deep learning-based fuse state determination apparatus 100 or may be included in a separate external device.

Referring to FIG. 1, the deep learning-based fuse state determination system 10 may further include the server 300.

As an embodiment, the server 300 may include a communication unit 310, a storage unit 320, and a calculation unit 330.

The communication unit 310 is a portion through which the server 300 communicates with the deep learning-based fuse state determination apparatus 100 and other devices outside the server 300, and a communication method is not particularly limited. For example, the communication unit 310 may use various wired and wireless communication methods including short-range wireless communication such as WiFi, Bluetooth, and NFC.

The storage unit 320 may store a fluoroscopic image of an object including a fuse. In addition, the storage unit 320 may store appraisal report data including fluoroscopic images of objects found at fire, explosion, or arson sites.

The calculation unit 330 may obtain user input text information related to a fuse state from the deep learning-based fuse state determination apparatus 100, and may provide a fluoroscopic image of an object including a fuse stored in the storage unit 320 based on the text information.

For example, the calculation unit 330 may receive a word input signal of ‘fuse’ and ‘melted’ by a user of the deep learning-based fuse state determination apparatus 100, and may search for and provide an appraisal report including a fluoroscopic image of a melted fuse from the appraisal report stored in the storage unit 320.

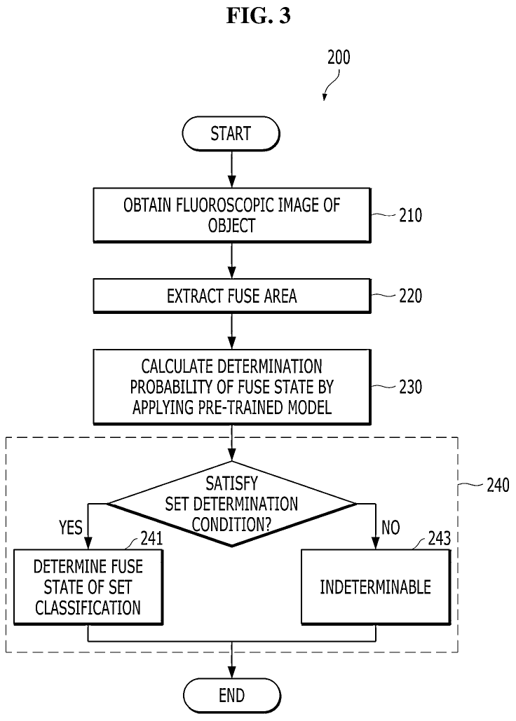

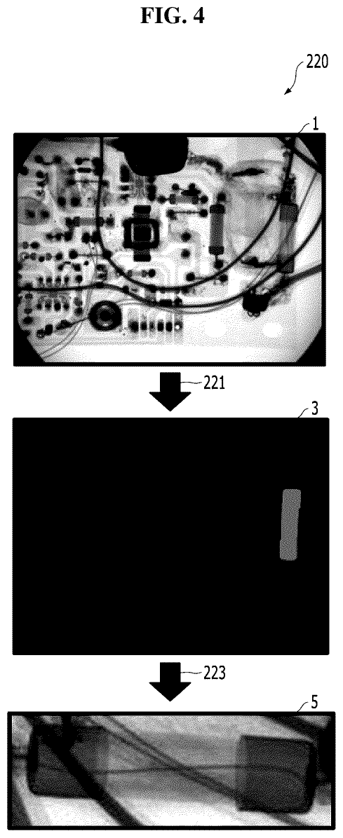

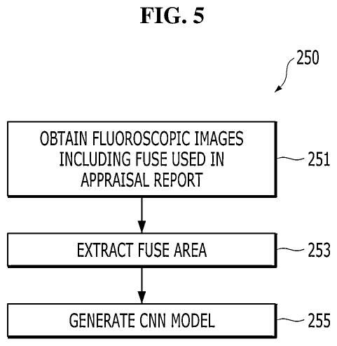

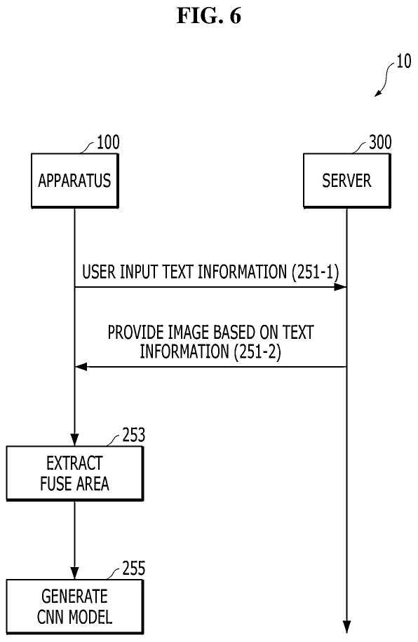

FIG. 3 is a flowchart illustrating a deep learning-based fuse state determination method according to an embodiment. FIG. 4 is a view for explaining extracting a fuse area from a fluoroscopic image of an object including a fuse. FIG. 5 is a flowchart illustrating generating a pre-trained model according to an embodiment. FIG. 6 is a view illustrating an operation according to a deep learning-based fuse state determination system according to an embodiment.

Referring to FIGS. 3 to 6, the deep learning-based fuse state determination method 200 according to an embodiment will be described. For convenience of description, the content overlapping with the deep learning-based fuse state determination apparatus 100 will be omitted or simplified.

Operation 210 is obtaining a fluoroscopic image of an object including a fuse.

Operation 210 may be performed by the image obtaining unit 110.

For example, the image obtaining unit 110 may obtain an X-ray image of an electric circuit board found at a fire site.

Operation 220 is extracting a fuse area from the fluoroscopic image of the object.

Operation 220 may be performed by the fuse area extraction unit 120.

In more detail, in operation 221, the fuse area extraction unit 120 constructs training data by generating an image labeled in units of pixels from a fluoroscopic image of an object including a plurality of fuses. In operation 223, the fuse area extraction unit 120 extracts a fuse area by using semantic segmentation based on the constructed training data.

Through operations 221 and 223, the fuse area extraction unit 120 may identify (3) the fuse area from an X-ray image (1) of the electric circuit board and may extract (5) the fuse area as shown in FIG. 4.

Operation 230 is calculating a probability (determination probability) of determining a fuse state of the extracted fuse area as a fuse state of a set classification by applying a pre-trained model.

Operation 230 may be performed by the trained model application unit 130.

For example, the fuse state of the set classification may include thermal fuse disconnection, thermal fuse non-disconnection, tubular fuse non-melting, tubular fuse melting or scattering, or tubular fuse flame melting.

Operation 240 is determining the fuse state of the extracted fuse area according to a set determination condition.

Operation 240 may be performed by the fuse state determination unit 140.

In more detail, in operation 240, the fuse state determination unit 140 determines the fuse state of the extracted fuse area as a fuse state that satisfies a set determination condition (operation 241), and when the fuse state does not satisfy the set determination condition, the fuse state determination unit 140 determines the fuse state as ‘indeterminable’ (operation 243).

The deep learning-based fuse state determination method 200 according to an embodiment may further include operation 250 of generating a pre-trained model.

In more detail, operation 250 is generating a pre-trained model using fluoroscopic images of an object including a fuse used in an appraisal report as training data.

Operation 250 may be performed by the trained model generation unit 150.

Operation 250 may include operations 251, 253, and 255.

Operation 251 is obtaining the fluoroscopic images of the object including the fuse used in the appraisal report.

In more detail, in operation 251-1, the deep learning-based fuse state determination apparatus 100 obtains user input text information related to a fuse state. In operation 251-2, the server 300 receives the user input text information and provides a fluoroscopic image of an object including a fuse based on the user input text information.

For example, a user of the deep learning-based fuse state determination apparatus 100 may input two words, ‘fuse’ and ‘melted’. The server 300 may receive the two words and provide images corresponding to the two words input by a user. The server 300 may provide an appraisal report including a fluoroscopic image of a “melted” “fuse” from among stored appraisal reports.

Operation 253 is extracting a fuse area from the fluoroscopic image of the object.

As described above, a fuse area may be extracted from a fluoroscopic image of an object using semantic segmentation.

Operation 255 is generating a CNN-based deep learning model (CNN model) by using an image of the extracted fuse area as training data.

In the case of extracting and learning only an image of a fuse area necessary for determining a fuse state using semantic segmentation, a resource shortage problem of a computing device may be solved.

According to embodiments, accuracy of determining a fuse state may be improved by applying an algorithm for extracting and analyzing a fuse area using semantic segmentation from among deep learning techniques.

According to embodiments, for a large number of images found at actual fire sites, CNN, a deep learning technique that classifies images by recognizing unique patterns of images, is used to extract common features, and based on this, a fuse state may be determined.

The deep learning-based fuse state determination method 200 according to an embodiment shown in FIG. 3 may be written as computer programs and may be implemented in general-use digital computers that execute the programs using a non-transitory computer-readable recording medium. The non-transitory computer-readable recording medium may be a magnetic storage medium (e.g., ROM, a floppy disk, a hard disk, etc.), or an optical reading medium (e.g., a CD ROM, a digital versatile disk (DVD) or the like).

It should be understood that embodiments described herein should be considered in a descriptive sense only and not for purposes of limitation. Descriptions of features or aspects within each embodiment should typically be considered as available for other similar features or aspects in other embodiments. Therefore, the scope of the disclosure is defined by the appended claims.

What is claimed is:

1. A deep learning-based fuse state determination apparatus comprising:
an image obtaining unit configured to obtain a fluoroscopic image of an object including a fuse;
a fuse area extraction unit configured to extract a fuse area from the fluoroscopic image of the object;
a trained model application unit configured to calculate a probability (determination probability) of determining a fuse state of the extracted fuse area as a fuse state of set classification by applying a pre-trained model; and
a fuse state determination unit configured to determine the fuse state of the extracted fuse area according to a set determination condition.

2. The deep learning-based fuse state determination apparatus of claim 1, wherein the fuse area extraction unit extracts the fuse area from the fluoroscopic image of the object by using semantic segmentation.

3. The deep learning-based fuse state determination apparatus of claim 1, wherein the fuse state of the set classification comprises thermal fuse disconnection, thermal fuse non-disconnection, tubular fuse non-melting, tubular fuse melting or scattering, or tubular fuse flame melting.

4. The deep learning-based fuse state determination apparatus of claim 1, wherein the set determination condition is to determine a fuse state having the highest determination probability and greater than or equal to a reference value from among fuse states of set classification.

5. The deep learning-based fuse state determination apparatus of claim 1, further comprising:
a trained model generation unit configured to generate the pre-trained model by using fluoroscopic images of an object including a fuse used in an appraisal report as training data.

6. The deep learning-based fuse state determination apparatus of claim 1, wherein the pre-trained model is a convolutional neural network (CNN)-based deep learning model.

7. A deep learning-based fuse state determination system comprising:
a deep learning-based fuse state determination apparatus configured to extract a fuse area from a fluoroscopic image of an object including a fuse and determine a fuse state of the extracted fuse area by applying a pre-trained model; and
a server receiving user input text information related to the fuse state and configured to provide a fluoroscopic image of an object including a fuse based on the user input text information.

8. A deep learning-based fuse state determination method comprising:
obtaining a fluoroscopic image of an object including a fuse;
extracting a fuse area from the fluoroscopic image of the object;
calculating a probability (determination probability) of determining a fuse state of the extracted fuse area as a fuse state of set classification by applying a pre-trained model; and
determining the fuse state of the extracted fuse area according to a set determination condition.

9. The deep learning-based fuse state determination method of claim 8, wherein the fuse state of the set classification comprises thermal fuse disconnection, thermal fuse non-disconnection, tubular fuse non-melting, tubular fuse melting or scattering, or tubular fuse flame melting.

10. The deep learning-based fuse state determination method of claim 8, further comprising:
generating the pre-trained model by using fluoroscopic images of an object including a fuse used in an appraisal report as training data.

11. The deep learning-based fuse state determination method of claim 10, wherein the generating of the pre-trained model comprises:
obtaining fluoroscopic images of an object including a fuse used in an appraisal report;
extracting a fuse area from the fluoroscopic image of the object; and
generating a CNN-based deep learning model by using an image of the extracted fuse area as training data.

12. The deep learning-based fuse state determination method of claim 11, wherein the obtaining of the fluoroscopic images of the object including the fuse used in the appraisal report comprises:
obtaining user input text information related to a fuse state; and
receiving, by a server, the user input text information and providing a fluoroscopic image of an object including a fuse based on the user input text information.
